(19) United States
(12) Patent Application Publication
(10) Pub. No.: US 2019/0178940 A1
(43) Pub. Date: Jun. 13, 2019

(54) System For Using Different Scan Chains To Test Differential Circuit, And Method Thereof

(71) Applicants: Inventec (Pudong) Technology Corporation, Shanghai (CN); Inventec Corporation, Taipei City (TW)

(72) Inventor: Qiu- Yue Duan, Shanghai (CN)

(21) Appl. No.: 16/009,877

(22) Filed: Jun. 15, 2018

(30) Foreign Application Priority Data
Dec. 9, 2017 (CN) 201711314457.X

(51) Int. Cl. G01R 31/3185; G01R 31/3177

(52) U.S. Cl. CPC G01R 31/318536; G01R 31/3177

(57) ABSTRACT

A system for using different scan chains to test differential circuit and a method thereof are disclosed. In the system, two scan chains are set up for two electronic components on a target circuit board, and test data for the two scan chains are sequentially pushed to the two scan chains respectively according to a data flow direction between the two scan chains, and after the electronic components output result data, a test result can be determined according to the test data for the two scan chains and the result data. This testing manner can be performed on all electronic components, so as to achieve the technical effect of stably performing differential signal test on all electronic components of the target circuit board.

### CROSS-REFERENCE TO RELATED APPLICATION

This application claims the benefit of Chinese Patent Application No. 201711314457.X, filed Dec. 9, 2017.

### BACKGROUND OF THE INVENTION

### Field of the Invention

The present invention generally relates to a circuit board testing system and a method thereof, more particularly to a system for using different scan chains to test a differential circuit, and a method thereof.

### Description of the Related Art

In recent years, the use of differential circuits for connecting different electronic components on a circuit board becomes very popular. Therefore, how to accurately test a differential circuit disposed between two electronic components is one of key issues that various manufacturers are eager to solve.

In general, the conventional method of testing the differential circuit usually performs a functional test to detect whether a differential signal can work normally. However, passing the functional test only indicates that the differential signal can be normally received and transmitted. If an open-circuit, a non-wetting of a capacitor, or a short-circuit occurs on a certain pin of an electronic component, such as “Tx_p” or “Rx_n”, the differential signal may still be transmitted as usual. In other words, the functional test is unable to test every line in the differential circuit and the test reliability thereof is poor.

In order to solve this problem, a test method using a Joint Test Action Group (JTAG) is developed, and a standard test access port and a boundary scan structure of each electronic component are used to test the differential circuit between two electronic components. However, currently, different electronic components must be tested by different test methods, and it increases the cost of testing.

Therefore, what is needed is to develop an improved technical solution to solve the conventional problem that different electronic components must be tested by different test methods.

### SUMMARY OF THE INVENTION

In order to solve the conventional problem that a user must select different test manners for different electronic components, the present invention is to provide a system for using different scan chains to test differential circuit, and a method thereof.

According to an embodiment, the present invention provides a system for using different scan chains to test differential circuit. The system is applied to test a target circuit board comprising two electronic components, and the two electronic components electrically connected to each other. The system comprises a signal input module; a test value defining module configured to define test values of a first scan chain and a second scan chain, wherein the first scan chain and the second scan chain correspond to the two electronic components respectively; a test data generating module configured to generate test data for the first scan chain and the second scan chain; a scan chain initialization module configured to use the test value for the first scan chain, through the signal input module, to initialize the first scan chain and use the test value for the second scan chain, through the signal input module, to initialize the second scan chain; a circuit test module configured to, according to a data flow direction between the first scan chain and the second scan chain, through the signal input module, sequentially push the test data for the first scan chain to the first scan chain and the test data for the second scan chain to the second scan chain; a signal acquisition module configured to obtain result data; and, a result determining module configured to determine a test result, according to the test data for the first scan chain and the second scan chain and the result data.

According to an embodiment, the present invention provides a method for using different scan chains to test differential circuit. The method is applied to test a target circuit board comprising two electronic components, and the two electronic components are electrically connected to each other. The method comprises steps of: defining test values of a first scan chain and a second scan chain, wherein the first scan chain and the second scan chain correspond to the two electronic components respectively; using the test value of the first scan chain, through the signal input module, to initialize the first scan chain and using the test value of the second scan chain, through the signal input module, to initialize the second scan chain; generating test data corresponding to the first scan chain and the second scan chain, respectively; according to a data flow direction between the first scan chain and the second scan chain, sequentially pushing the test data for the first scan chain to first scan chain and the test data for the second scan chain to the second scan chain, through signal input module; obtaining result data by a signal acquisition module; and, determining a test result according to the test data for the first scan chain and the second scan chain and the result data.

According to above content, the difference between the system and method of the present invention and the conventional technology is that the system and method of the present invention can set up two scan chains for two electronic components on the target circuit board, and sequentially push the test data for the two scan chain to two scan chains respectively according to the data flow direction between the two scan chains; and, after the electronic components output the result data, the test result can be determined according to test data for the two scan chains and the result data, so as to solve the conventional problem and achieve technical effect of stably performing differential signal test on all electronic components.

### BRIEF DESCRIPTION OF THE DRAWINGS

The structure, operating principle and effects of the present disclosure will be described in detail by way of various embodiments which are illustrated in the accompanying drawings.

FIG. 1 is a framework diagram of a system for using different scan chains to test differential circuit, according to an embodiment of the present invention.

FIG. 2 is a flow chart of a method for using different scan chains to test differential circuit, according to an embodiment of the present invention.

### DETAILED DESCRIPTION OF THE PREFERRED EMBODIMENTS

The following embodiments of the present disclosure are herein described in detail with reference to the accompanying drawings. These drawings show specific examples of the embodiments of the present disclosure. It is to be understood that these embodiments are exemplary implementations and are not to be construed as limiting the scope of the present disclosure in any way. Further modifications to the disclosed embodiments, as well as other embodiments, are also included within the scope of the appended claims. These embodiments are provided so that this disclosure is thorough and complete, and fully conveys the inventive concept to those skilled in the art. Regarding the drawings, the relative proportions and ratios of elements in the drawings may be exaggerated or diminished in size for the sake of clarity and convenience. Such arbitrary proportions are only illustrative and not limiting in any way. The same reference numbers are used in the drawings and description to refer to the same or like parts.

It is to be understood that, although the terms ‘first’, ‘second’, ‘third’, and so on, may be used herein to describe various elements, these elements should not be limited by these terms. These terms are used only for the purpose of distinguishing one component from another component. Thus, a first element discussed herein could be termed a second element without altering the description of the present disclosure. As used herein, the term “or” includes any and all combinations of one or more of the associated listed items.

It will be understood that when an element or layer is referred to as being “on,” “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present.

In addition, unless explicitly described to the contrary, the word “comprise” and variations such as “comprises” or “comprising”, will be understood to imply the inclusion of stated elements but not the exclusion of any other elements.

The system and the method of the present invention can detect whether the circuit connected to two electronic components on a target circuit board is normal. The electronic component can be an integrated circuit, however, the present disclosure is not limited thereto.

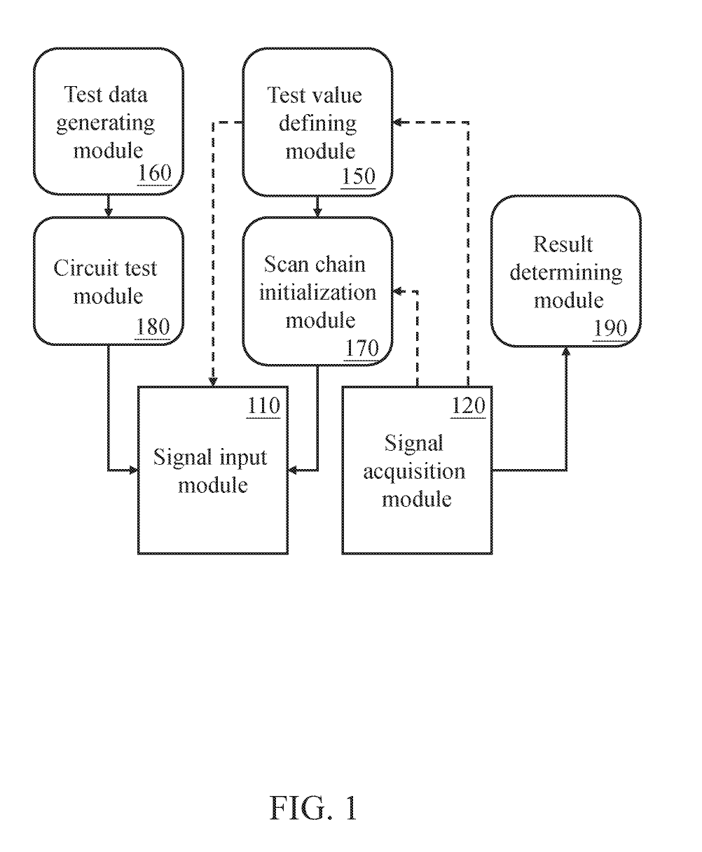

The operation of the system of the present invention can be illustrated in cooperation with the structural view shown in FIG. 1. As shown in FIG. 1, the system of the present invention comprises a signal input module 110, a signal acquisition module 120, a test value defining module 150, a test data generating module 160, a scan chain initialization module 170, a circuit test module 180, and a result determining module 190.

The signal input module 110 is configured to push signals to electronic components on a circuit board. The circuit board can be a target circuit board to be tested, or a sample circuit board which is confirmed to work normally. The sample circuit board and the target circuit board can have the same the models, specifications and layouts, that is, the sample circuit board and the target circuit board are the same circuit boards.

The signal input module 110 can comprises one or more input components each can be a one-dimensional shift register or a multi-dimensional shift register; however, the present invention is not limited thereto. Each input component is electrically connected to an electronic component on the target circuit board through a specific pin or a specific contact point of the electronic component.

Each input component included in the signal input module 110 can be electrically coupled to one or more electronic components on the same target circuit board. When the input component is electrically coupled to only one electronic component, the input component can push a set of signals to the electronic component electrically connected thereto. When the input component is electrically coupled to multiple electronic components, the input component can select one of the electronic components electrically connected thereto, and push a set of signals to the selected electronic component.

The signal acquisition module 120 is configured to obtain the signals generated by an electronic component on a circuit board. The circuit board can be the target circuit board to be tested or a sample circuit board which is confirmed to work normally. However, the signal acquisition module 120 and the signal input module 110 both must be electrically coupled to the electronic component on the same circuit board.

Similarly, the signal acquisition module 120 can comprise one or more acquisition components each can be a one-dimensional shift register or a multi-dimensional shift register; however, the present invention is not limited thereto. Each acquisition component is electrically coupled to an electronic component of the target circuit board through a specific pin or specific contact point of the electronic component on the target circuit board.

Each acquisition component included in the signal acquisition module 120 can be electrically coupled to one or more electronic components on the same target circuit board. When the acquisition component is electrically coupled to only one electronic component, the acquisition component receives a set of signals generated by the electronic component electrically connected thereto. When the acquisition component is electrically coupled to multiple electronic components, the acquisition component can select one of the electronic components electrically connected thereto, and receive a set of signals generated by the selected electronic component.

It is to be noted that, in an embodiment, an electronic component on the target circuit board, one input component of the signal input module 110 electrically coupled to the electronic component, and one acquisition component of the signal acquisition module 120 electrically coupled to the electronic component can form a scan chain corresponding to the electronic component; in other words, one scan chain corresponding to one electronic component on the target circuit board, can comprise the electronic component corresponding thereto, the input component electrically coupled to the electronic component corresponding thereto, and the acquisition component electrically coupled to the electronic component corresponding thereto. In an embodiment, the target circuit board comprises at least two electronic components disposed thereon, so the system of the embodiment comprises at least two scan chains which are referred as a first scan chain and a second scan chain, respectively. Furthermore, the electronic components corresponding to the first scan chain and the second scan chain are referred as a first electronic component and a second electronic component, respectively.

The test value defining module 150 is configured to define a test value of a scan chain, for example, the test values of the first scan chain and the second scan chain. In an embodiment, a first test value and a second test value are used to indicate the test value of the first scan chain and the test value of the second scan chain, respectively.

The test value defining module 150 is configured to transmit, through the signal input module 110, a testing instruction to a sample component on a sample circuit board, and also obtain, through the signal acquisition module 120, sample data from the sample component on the sample circuit board, and then define the obtained sample data as the test value of the scan chain. The test value defining module 150 can also define a preset value as the test value of the scan chain. The sample component and the second electronic component have the same model number and specification, and the position and the function of the sample component on the sample circuit board is the same as that of the second electronic component on the target circuit board.

The test data generating module 160 is configured to generate test data corresponding to the scan chain, that is, the test data generating module 160 generate the test data corresponding to the first scan chain and the second scan chain respectively. For example, according to identification data of the target circuit board, identification data of the first electronic component and identification data of the second electronic component, the test data generating module 160 can read the test data corresponding to the first scan chain and the second scan chain; however, the manner used by the test data generating module 160 to generate the test data is not limited to above-mentioned example.

The scan chain initialization module 170 is configured to use, through the signal input module 110, the first test value to initialize the first scan chain, and use, through the signal input module 110, the second test value to initialize the second scan chain.

In greater detail, the scan chain initialization module 170 pushes, through the signal input module 110, a sampling instruction (such as SAMPLE instruction), the first test value defined by the test value defining module 150, the first test value (transmitted again), a testing instruction (such as the EXTEST instruction), and the first test value (transmitted for the third time) to the first electronic component in a sequential order; and obtain the sampling data from the first electronic component through the signal acquisition module 120, and the scan chain initialization module 170 then uses the obtained sampling data as a new first test value, and pushes, through the signal input module 110, the new first test value and a pulse instruction (such as the EXTEST_PULSE instruction) to the first electronic component in a sequential order. Next, the scan chain initialization module 170 repeats to use the sampling data obtained by the signal acquisition module 120 as the new first test value, and transmit the changed first test value to the first electronic component through the signal input module 110, and obtains, through the signal acquisition module 120, the sampling data from the first electronic component for several times, thereby initializing the first scan chain. Similarly, the scan chain initialization module 170 can use aforementioned process of initializing the first scan chain to initialize the second scan chain; for example, the SAMPLE instruction, the second test value, the second test value (transmitted again), the EXTEST instruction, the second test value (transmitted for the third time), the sampling data (the new second test value), and the EXTEST_PULSE instruction can be pushed, through the signal input module 110, to the second electronic component in a sequential order, and the scan chain initialization module 170 can repeat to push the sampling data, which is used as the new second test value, for several times, so as to initialize the second scan chain.

After the test for the circuit test module 180 is completed, the scan chain initialization module 170 can push, through the signal input module 110, the EXTEST instruction and the final first test value pushed to the first scan chain in a sequential order, to the first scan chain, so as to make the first scan chain back to an initial status. Similarly, after the test for the circuit test module 180 is completed, the scan chain initialization module 170 can push, through the signal input module 110, the EXTEST instruction and the final second test value of the second scan chain to the second scan chain in a sequential order, so as to make the second scan chain back to the initial status.

The circuit test module 180 is configured to sequentially push, according to the data flow direction between the electronic component corresponding to the first scan chain and the electronic component corresponding to the second scan chain, through the signal input module 110, the test data for the first scan chain to the first scan chain and the test data for second scan chain generated by the test data generating module 160, to the second scan chain. For example, in order to test whether the data or signal pushed from the first electronic component to the second electronic component is correct, the circuit test module 180 can first push, through the signal input module 110, the test data for the first scan chain to the first scan chain, and then push the test data for the second scan chain to the second scan chain; in the other hand, in order to test whether the data or signal pushed from the second electronic component to the first electronic component is correct, the circuit test module 180 can first push, through the signal input module 110, the test data for the second scan chain to the second scan chain, and then push the test data for the first scan chain to the first scan chain.

It is worth noting that the test data pushed by the circuit test module 180 to the scan chain (such as the first scan chain and the second scan chain) through the signal input module 110 is to change the signal of the to-be-tested pin only, so that the signal of the pin not being tested is not changed, thereby ensuring that the test data pushed by the circuit test module 180 to the scan chain can meet actual work logic of the motherboard, and preventing the electronic component from generating unexpected data or signal to cause unexpected condition (such as interruption of power supply) of the motherboard.

The circuit test module 180 is configured to obtain result data through the signal acquisition module 120. The result data obtained by the circuit test module 180 can comprise an output result of the first electronic component and an output result of the second electronic component.

In some embodiments, the electronic component, which is planned to late obtain the test data, may generate unknown result, in a condition that the electronic component (such as the second electronic component), which is planned to late obtain the test data pushed by the circuit test module 180 through the signal input module 110, may obtain the test data before the electronic component (such as the first electronic component), which more earlier obtains the test data pushed by the signal input module 110 through the circuit test module 180, generates the output signal, or in a condition that the output signal generated by the electronic component, which more earlier obtains the test data pushed by the circuit test module 180, is not yet transmitted to the electronic component which is planned to late obtain the test data. In order to prevent this situation, the circuit test module 180 can push, according to the sequence of pushing the test data for the first scan chain/second scan chain last time, the test data for the first scan chain/second scan chain generated by the test data generating module 160 to the first scan chain/second scan chain once again through the signal input module 110, thereby preventing the data or the signal of the first electronic component and the second electronic component from being non-synchronous.

The result determining module 190 is configured to determine test result according to the test data for the first scan chain and the test data for the second scan chain pushed by the circuit test module 180 through the signal input module 110, and the result data obtained by the circuit test module 180 through the signal acquisition module 120.

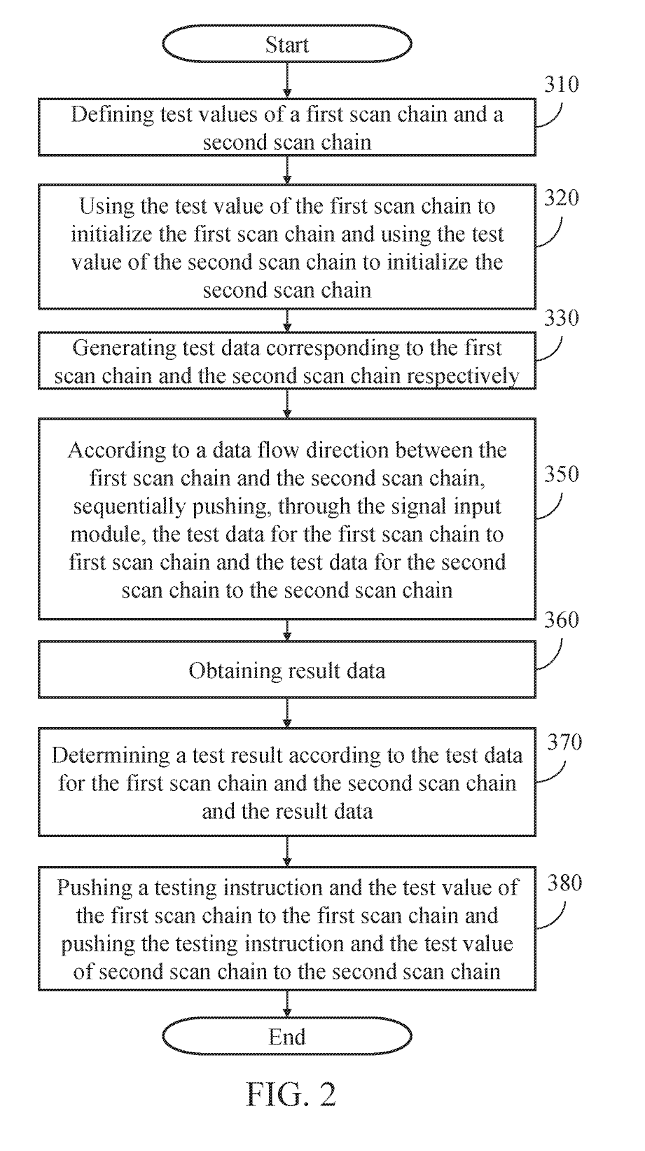

Next, the operations of the system and the method of the present invention are illustrated according to an embodiment. Please refer to FIG. 2, which is a flow chart of a method for using different scan chains to test differential circuit. In this embodiment, the target circuit board can be a motherboard, the first electronic component can be a SATA control chip, the second electronic component can be a PCH chip, a bi-directional differential circuit is disposed between the first electronic component and the second electronic component; however, the present disclosure is not limited thereto. The method comprises steps 310 to 380.

In the step 310, in order to test the circuit disposed between the first electronic component and the second electronic component, the test value defining module 150 defines the test values of the first scan chain and the second scan chain. In this embodiment, the test value defining module 150 uses a preset value to define the test value of the first scan chain, for example, all bits of the test value of the first scan chain are defined to be 1. Furthermore, the signal input module 110 and the signal acquisition module 120 are electrically coupled to the sample component first, so that the test value defining module 150 can push, through the signal input module 110, the EXTEST instruction to the sample component of the sample circuit board, and the test value defining module 150 can obtain, through the signal acquisition module 120, the sample data from the sample component on the sample circuit board, so as to define the sample data obtained by the signal acquisition module 120 as the test value of the second scan chain.

After the test value defining module 150 defines the test values of the first scan chain and the second scan chain in the step 310, in the step 320, the scan chain initialization module 170 uses the first test value, defined by the test value defining module 150, to initialize the first scan chain, and use the second test value, defined by the test value defining module 150, to initialize the second scan chain. In this embodiment, the scan chain initialization module 170 can perform the following steps for the first scan chain and the second scan chain respectively. In these steps, the scan chain initialization module 170 first pushes, through the signal input module 110, the SAMPLE instruction, the test value of the scan chain, the test value of the scan chain (transmitted again), the EXTEST instruction, the test value of the scan chain (transmitted for the third time) to the electronic component corresponding to the scan chain, in a sequential order; and the scan chain initialization module 170 obtains, through the signal acquisition module 120, the sampling data outputted from the electronic component corresponding to the scan chain; next, the scan chain initialization module 170 uses the obtained sampling data as the new test value, and pushes, through the signal input module 110, the new test value and the EXTEST_PULSE instruction to the electronic component corresponding to the scan chain again, in a sequential order; next, the scan chain initialization module 170 obtains, through the signal acquisition module 120, the sampling data outputted from the electronic component corresponding to the scan chain, and replaces the test value by the finally-obtained sampling data, and the scan chain initialization module 170 pushes, through the signal input module 110, the new test value to the electronic component corresponding to the scan chain. These steps of obtaining the sampling data outputted from the electronic component corresponding to the scan chain, and using the obtained sampling data as the new test value, and pushing the new test value to the electronic component corresponding to the scan chain are repeated for several times, to initialize the first scan chain and the second scan chain.

After the test value defining module 150 defines the test values of the first scan chain and the second scan chain (in the step 310), in the step 330, the test data generating module 160 generates the test data for the first scan chain and the second scan chain respectively.

In actual application, the operations of the scan chain initialization module 170 and the test data generating module 160 are not performed in a fixed order; in other words, the scan chain initialization module 170 can use the first test value and the second test value to initialize the first scan chain and the second scan chain respectively (that is, the step 320) after the test data generating module 160 generates the test data for the first scan chain and the second scan chain (that is, the step 330).

After the scan chain initialization module 170 uses the first test value and the second test value to initialize the first scan chain and the second scan chain respectively, (that is, the step 320) and the test data generating module 160 generates the test data for the first scan chain and the second scan chain (that is, the step 330), in the step 350, the circuit test module 180 can sequentially push, according to the data flow direction between the first electronic component and the second electronic component, the test data for the first scan chain to first scan chain and the test data for second scan chain to the second scan chain, through the signal input module 110; in the step 360, the result determining module 190 obtains, through the signal acquisition module 120, the result data containing the signals outputted from the first electronic component and the second electronic component. In this embodiment, the circuits between the first electronic component and the second electronic component are bi-directional, that is, the circuits between the first electronic component and second electronic component and configured to transmit and receive data or signal are not shared with each other, so the circuit test module 180 must test the circuit in which data or signal is transmitted from the first electronic component to the second electronic component, and also test the circuit in which data or signal is transmitted from the second electronic component to the first electronic component. After a test jig is electrically connected to the SATA slot on the target circuit board, the circuit test module 180 can first test the circuit in which data or signal is transmitted from the first electronic component to the second electronic component, and the circuit test module 180 can push the test data for the first scan chain to the first scan chain through the signal input module 110, and then push the test data for the second scan chain to the second scan chain through signal input module 110. As a result, the first electronic component can pass, according to the received test data for the first scan chain, the data transmitted from the test jig, to the second electronic component, so that the result determining module 190 can obtain the signal outputted from the first electronic component through the signal acquisition module 120, respectively. Similarly, the second electronic component can pass, according to the received test data for the second scan chain, the data from the first electronic component, so that the result determining module 190 can obtain the signal outputted from the second electronic component through the signal acquisition module 120, respectively. Next, the circuit test module 180 continues to test the circuit in which data or signal is transmitted from the second electronic component to the first electronic component, and the circuit test module 180 pushes the test data for the second scan chain to the second scan chain through the signal input module 110 first, and then pushes the test data for the first scan chain to the first scan chain through signal input module 110; next, the result determining module 190 can obtain, through the signal acquisition module 120, the signals outputted from the first electronic component and the second electronic component, respectively, and use the signals obtained after the test data for the first scan chain are pushed, and the signals obtained after the test data for the second scan chain are pushed, as the result data.

After the result determining module 190 obtains the result data through signal acquisition module 120 (that is, the step 360), in the step 370, the result determining module 190 can determine the test result according to the obtained result data, and the test data generated by the test data generating module 160 for the first scan chain and the second scan chain.

To summary, the difference between the technology of the present invention and the conventional technology is that the system and method of the present invention can set up scan chains for the two electronic components on the target circuit board, and sequentially push test data for the two scan chains to two scan chains respectively according to the data flow direction between the two scan chains, and after the electronic components generate the result data, the test result can be determined according to the result data and the test data for the two scan chains. The technical solution can solve the conventional problem that the user must select different testing manners for different electronic components, and achieve technical effect of stably performing differential signal test on all electronic components.

In the embodiment, after according to the data flow direction between the first electronic component and the second electronic component, the circuit test module 180 sequentially pushes the test data for the first scan chain to first scan chain and the test data for the second scan chain to the second scan chain, through the signal input module 110 (that is, the step 350), in the step 360, the circuit test module 180 can sequentially push the test data for the first scan chain and the second scan chain to the first scan chain and the second scan chain, respectively once again, and the result determining module 190 obtains, through the signal acquisition module 120, the result data containing the signals outputted from the first electronic component and the second electronic component.

Furthermore, in the embodiment, if the test process is not only performed for the circuit between the two electronic component on the target circuit board, after the result determining module 190 obtains, through the signal acquisition module 120, the result data containing the signals outputted from the first electronic component and the second electronic component (that is, the step 360), in the step 380, the scan chain initialization module 170 can push, through the signal input module 110, the EXTEST instruction and the first test value to the first scan chain, to make the first scan chain back to the initial status, and the scan chain initialization module 170 also can push, through the signal input module 110, the EXTEST instruction and the second test value to the second scan chain, to make the second scan chain back to the initial status.

In an embodiment, the method and the system for using different scan chains to test differential circuit, can be implemented by hardware, software or a combination thereof, and can also be implemented by a centralization manner using a computer system, or by a distribution manner using different components distributed in interconnect computer systems.

The present invention disclosed herein has been described by means of specific embodiments. However, numerous modifications, variations and enhancements can be made thereto by those skilled in the art without departing from the spirit and scope of the disclosure set forth in the claims.

What is claimed is:

1. A method for using different scan chains to test differential circuit, wherein the method is applied to test a target circuit board comprising two electronic components, and the two electronic components are electrically connected to each other, and the method comprises:
defining test values of a first scan chain and a second scan chain, wherein the first scan chain and the second scan chain correspond to the two electronic components respectively;
using the test value of the first scan chain, through a signal input module, to initialize the first scan chain and using the test value of the second scan chain, through the signal input module, to initialize the second scan chain;
generating test data corresponding to the first scan chain and the second scan chain respectively;
according to a data flow direction between the first scan chain and the second scan chain, sequentially pushing, through the signal input module, the test data for the first scan chain to first scan chain and the test data for the second scan chain to the second scan chain;
obtaining result data through a signal acquisition module; and
determining a test result according to the test data for the first scan chain and the second scan chain and the result data.

2. The method according to claim 1, wherein the step of defining the test value of the first scan chain, further comprises:
transmitting, through the signal input module, a testing instruction to a sample component of a sample circuit board; and
receiving, through the signal acquisition module, sample data outputted from the sample component; and
defining the sample data as the test value of the first scan chain.

3. The method according to claim 1, wherein the step of using, through the signal input module, the test value of the first scan chain to initialize the first scan chain and using through the signal input module, the test value of the second scan chain to initialize the second scan chain, further comprises:
transmitting, through the signal input module, a sampling instruction, the test value corresponding to the first scan chain/the second scan chain, the test value corresponding to the first scan chain/the second scan chain, a testing instruction, and the test value corresponding to the first scan chain/the second scan chain, in a sequential order, to the electronic component corresponding to the first scan chain/the second scan chain;
receiving, through the signal acquisition module, sampling data outputted from the electronic component corresponding to the first scan chain/the second scan chain;
using the sampling data as the test value corresponding to the first scan chain/the second scan chain;
transmitting, through the signal input module, the test value corresponding to the first scan chain/the second scan chain and a pulse instruction to the electronic component corresponding to the first scan chain/the second scan chain; and
repeating the following steps: using the sampling data received by the signal input module from the electronic component corresponding to the first scan chain/the second scan chain, as the test value corresponding to the first scan chain/the second scan chain and transmitting the test value corresponding to the first scan chain/the second scan chain to the electronic component corresponding to the first scan chain/the second scan chain, through the signal input module.

4. The method according to claim 1, wherein the step of sequentially pushing, through the signal input module, the test data for the first scan chain to first scan chain and the test data for the second scan chain to the second scan chain, according to the data flow direction between the first scan chain and the second scan chain, further comprises:
sequentially pushing, through the signal input module, the test data for the first scan chain to first scan chain and the test data for the second scan chain to the second scan chain, once again.

5. The method according to claim 1, wherein after the step of obtaining the result data through the signal acquisition module, the method further comprises:
pushing, through the signal input module, a testing instruction and the test value of the first scan chain to the first scan chain, and pushing, through the signal input module, the testing instruction and the test value of the second scan chain to the second scan chain.

6. A system for using different scan chains to test differential circuit, wherein the system is applied to test a target circuit board comprising two electronic components, and the two electronic components are electrically connected to each other, and the system comprises:
a signal input module;
a test value defining module configured to define test values of a first scan chain and a second scan chain, wherein the first scan chain and the second scan chain correspond to the two electronic components respectively;
a test data generating module configured to generate test data corresponding to the first scan chain and the second scan chain;
a scan chain initialization module configured to use the test value of the first scan chain, through the signal input module, to initialize the first scan chain, and use the test value of the second scan chain, through the signal input module, to initialize the second scan chain;
a circuit test module configured to sequentially push, according to a data flow direction between the first scan chain and the second scan chain, the test data for the first scan chain to the first scan chain and the test data for the second scan chain to the second scan chain through the signal input module;
a signal acquisition module configured to obtain result data; and
a result determining module configured to determine a test result according to the test data for the first scan chain and the second scan chain and the result data.

7. The system according to claim 6, wherein the test value defining module is configured to define sample data, which is obtained by the signal acquisition module from a sample component of a sample circuit board, as the test value of the first scan chain, wherein the sample data is generated by the sample component according to a testing instruction transmitted from the signal input module.

8. The system according to claim 6, wherein the scan chain initialization module transmits a sampling instruction, the test value corresponding to the first scan chain/the second scan chain, the test value corresponding to the first scan chain/the second scan chain, a testing instruction, and the test value corresponding to the first scan chain/the second scan chain in a sequential order, to the electronic component corresponding to the first scan chain/the second scan chain through the signal input module;
wherein after the scan chain initialization module obtains, through the signal acquisition module, sampling data from the electronic component corresponding to the first scan chain/the second scan chain, the scan chain initialization module use the sampling data as the test value corresponding to the first scan chain/the second scan chain, and then pushes, through the signal input module, a pulse command and the test values corresponding to the first scan chain/the second scan chain to the electronic component corresponding to the first scan chain/the second scan chain, in a sequential order;
wherein the scan chain initialization module repeat to use, the sampling data obtained by the signal acquisition module from the electronic component corresponding to the first scan chain/the second scan chain, as the test value corresponding to the first scan chain/the second scan chain and transmit the changed test value to the electronic components corresponding to the first scan chain/the second scan chain, through the signal input module.

9. The system according to claim 6, wherein the circuit test module further pushes the test data for the first scan chain to the first scan chain and the test data for the second scan chain to the second scan chain once again, through the signal input module.

10. The system according to claim 6, wherein the scan chain initialization module further pushes, through the signal input module, a testing instruction and the test value of the first scan chain to the first scan chain, and pushes, through the signal input module, the testing instruction and the test value of the second scan chain to the second scan chain.
